(19) United States
(12) Patent Application Publication
(10) Pub. No.: US 2007/0274362 A1
(43) Pub. Date: Nov. 29, 2007

(54) Semiconductor device

(75) Inventors: Isao Hayami, Hyogo (JP); Shoichi Tanaka, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/783,853

(22) Filed: Apr. 12, 2007

(30) Foreign Application Priority Data
May 24, 2006 (JP) 2006-143457

(51) Int. Cl. H01S 5/026

(52) U.S. Cl. 372/50.21

(57) ABSTRACT

A high-power semiconductor laser chip 39 with a long cavity length is disposed on a side 42 of a Si chip 37 along the long side of a package, thereby reducing the thickness and size of a semiconductor device 30 for integrating the semiconductor laser chip 39 and a light-receiving element for signal processing. Further, by using the semiconductor device 30, it is possible to reduce the thickness and size of an optical pickup and the thickness and size of an optical disc drive using the optical pickup.

### FIELD OF THE INVENTION

The present invention relates to a semiconductor device used for reading and writing of a rewritable optical disc and including an integrated semiconductor laser chip and light receiving elements, a method of fabricating the same, an optical pickup including the semiconductor device, and an optical disc drive.

### BACKGROUND OF THE INVENTION

In recent years, large-capacity rewritable optical discs loaded in DVD recorders and personal computers have rapidly become widespread. Particularly in portable equipment such as notebook computers, thin and small optical disc drives are strongly demanded.

In order to achieve thin and small optical disc drives, it is important to slim down and miniaturize optical pickups. For this purpose, it is expected that slimming down and miniaturization are achieved by reexamining the internal structures of main components while keeping the performance and functions of main components in the optical designs and mechanical designs of optical pickups.

For example, the main components of an optical pickup include a semiconductor laser and light-receiving elements for detecting signals. The semiconductor laser and the light-receiving elements for detecting signals are integrated in a package to make up a semiconductor device. The size and thickness of the optical pickup are reduced by the integration of the semiconductor device and also by reducing the number of components in the optical pickup.

Referring to FIG. 9, the configuration of an integrated optical element in a conventional integrated semiconductor device will be described below as an example.

FIG. 9A is a schematic drawing showing the integrated optical element acting as a main part of the conventional semiconductor device. FIG. 9B is a schematic block diagram showing the internal configuration of the conventional semiconductor device.

In FIG. 9A, light-receiving elements 3 are formed on a major surface 2 of a Si substrate 1, and simultaneously a semiconductor laser chip 5 is bonded to an underside 4 in a concave portion formed on the major surface 2. Further, on a concave portion side opposed to the laser beam emitting surface of the semiconductor laser chip 5, a mirror surface 6 is formed at an angle of 45° with respect to the major surface 2 of the Si substrate 1. The mirror surface 6 is a part of an inclined surface of a V-shaped groove etched in the concave portion. In this way, the light-receiving elements 3 for detecting signals and the semiconductor laser chip 5 are integrated on the Si substrate 1 and make up an integrated optical element 12.

A laser beam 7 is emitted from the emitting surface of the semiconductor laser chip 5 of the integrated optical element 12. The laser beam 7 is reflected on a reflection position 8 of the mirror surface 6 and then is emitted upward in a direction perpendicular to the major surface 2 of the Si substrate 1. The laser beam is guided to an optical disc by the optical system of the optical pickup. The laser beam is reflected after reading signals recorded on the optical disc, returned to the integrated optical element 12, and is incident on the light-receiving elements 3 for detecting signals, so that signals recorded on the optical disc and an error signal of a servo mechanism are detected.

FIG. 9B is a schematic diagram showing the overall configuration of a semiconductor device 10 without the top of the package thereof. The integrated optical element 12 is bonded on a metal base 11 of a package bottom 9. The light-receiving elements 3 and the semiconductor laser chip 5 are integrated in the integrated optical element 12. A laser beam emitted from the semiconductor laser chip 5 is reflected on the reflection position 8 of the mirror surface 6 and then emitted perpendicularly to the major surface 2. The laser beam returns from the optical disc and is incident on the light-receiving elements 3. A detected optical signal is converted to an electric signal and is subjected to signal processing in a circuit of the integrated optical element 12. After that, the signal is extracted to an external circuit through lead terminals 13 of the package bottom 9. In this way, the light-receiving elements 3 for detecting signals and the semiconductor laser chip 5 are integrated as the same integrated optical element 12, so that the size and thickness of the semiconductor device 10 are reduced. In other words, it is possible to reduce a short side length 21 of the semiconductor device 10. The short side length 21 determines the thickness of the optical pickup.

With the semiconductor device 10 configured thus, the size and thickness of the optical pickup can be reduced (conventional example 1).

FIG. 10 shows an example a conventional optical pickup 20 using the semiconductor device 10 configured thus.

FIG. 10 is a schematic diagram showing the conventional optical pickup including the conventional semiconductor device.

In FIG. 10, the semiconductor device 10 is mounted in a housing 14 of the optical pickup 20. The semiconductor device 10 is integrated such that a package top 15 is bonded on the package bottom 9 shown in FIG. 9B. A diffractive optical element is formed in the package top 15. In this configuration, the semiconductor device 10 and an optical disc 16 are optically coupled to each other via an optical component 17 acting as a collimate lens, a raising mirror 18, and an objective lens 19. To be specific, the laser beam 7 emitted from the semiconductor laser chip (not shown) of the semiconductor device 10 shown in FIG. 9 is collimated into a parallel beam by the optical component 17 and the optical path is bent by 90° by the raising mirror 18. After that, the laser beam 7 is brought into focus by the objective lens 19, on a pit recorded on the optical disc 16. The laser beam 7 having read a signal on the pit is reflected on the optical disc 16 and travels backward the same path to return to the semiconductor device 10. At this point, the laser beam 7 is split by the diffractive optical element (not shown) formed in the package top 15 of the semiconductor device 10 and is incident on light-receiving elements (not shown), and a signal recorded on the optical disc is read.

In order to reduce the thickness of the optical pickup 20 configured thus, it is preferable to reduce the short side length 21 of the semiconductor device 10. Further, in order to reduce the size of the optical pickup 20, it is preferable to reduce a height 22 of the semiconductor device 10. However, if the semiconductor laser chip 5 and the light-receiving elements 3 are not integrated in the semiconductor device 10 as shown in FIG. 9A, another optical element for optically coupling these elements is necessary or a package is necessary for each of the elements, interfering with the miniaturization and slimming down of the optical pickup 20.

Moreover, there is proposed a configuration of an integrated optical element (conventional example 2). In this configuration, unlike FIG. 9, light-receiving elements and a semiconductor laser chip are not mounted on a plane but are three-dimensionally mounted and integrated on a metal block, not on a Si substrate. To be specific, by cutting one side wall of the protective cap of the integrated optical element, a short side length 21 corresponding to the thickness of the optical pickup of FIG. 10 is reduced by the cut thickness in this integrated optical element.

However, in the future, high-power semiconductor lasers will be demanded as rewritable optical discs have larger capacities and become faster. Thus in the semiconductor device of conventional example 1, the longer the cavity length of the semiconductor laser, the longer the short side of the semiconductor device, interfering with the slimming down of the optical pickup.

Further, in conventional example 2, as high-power semiconductor lasers are similarly demanded and the cavity lengths of lasers increase, the height of the semiconductor device of conventional example 2 increases, interfering with the miniaturization of the optical pickup.

The present invention proposes a new configuration of integration for solving the conventional problems. In this configuration, the short side of a semiconductor device is short and the height of the semiconductor device is low in the integration of a semiconductor laser chip used for a rewritable optical disc and light-receiving elements for processing signals. An object of the present invention is to reduce the thickness and size of a semiconductor device by using the new configuration of integration, and provide a thin and small optical pickup using the semiconductor device and a thin and small optical disc including the optical pickup.

### DISCLOSURE OF THE INVENTION

In order to attain the object, a semiconductor device of the present invention is a semiconductor device for emitting and receiving a laser beam, comprising: a package for packaging the semiconductor device, a Si chip formed on the base of the package and including one or a plurality of light-receiving elements for detecting a signal, a semiconductor laser chip disposed on Si chip side adjacent to a connection surface with the base such that a cavity length direction and the long side direction of the package are aligned with each other, the semiconductor laser chip emitting a laser beam from an end face of the semiconductor laser chip, a mirror portion having a reflection plane for reflecting the laser beam perpendicularly to the major surface of the package, and a lead terminal electrically connected to an electrode of the Si chip and serving as an external electrode of the semiconductor device.

With this configuration, even when a semiconductor laser chip emitting a high-power laser beam is mounted with a long cavity length, it is possible to achieve a thin and small semiconductor device capable of further increasing the power of the laser beam.

Further, the Si chip and the mirror portion are integrated into a single part. With this configuration, only by adjusting the position of the semiconductor laser chip, it is possible to more easily adjust a positional relationship among the Si chip having the light-receiving element formed thereon, the semiconductor laser chip, and the mirror portion.

Moreover, the Si chip and the mirror portion are separated from each other. With this configuration, the Si chip and the mirror portion can be separately fabricated with a simple fabrication process, thereby reducing the cost.

A semiconductor device for emitting and receiving a laser beam, comprising: a package for packaging the semiconductor device, a first Si chip formed on the base of the package and including one or a plurality of light-receiving elements for detecting a signal, a second Si chip formed on the base of the package and including one or a plurality of light-receiving elements for detecting a signal, a semiconductor laser chip disposed on a first Si chip side adjacent to a connection surface with the base such that a cavity length direction and the long side direction of the package are aligned with each other, the semiconductor laser chip emitting a laser beam from an end face of the semiconductor laser chip, a mirror portion formed on the second Si chip and having a reflection plane for reflecting the laser beam perpendicularly to the major surface of the package, and a lead terminal electrically connected to an electrode of one of the first Si chip and the second Si chip and serving as an external electrode of the semiconductor device.

With this configuration, even when a semiconductor laser chip emitting a high-power laser beam is mounted with a long cavity length, it is possible to achieve a thin and small semiconductor device capable of further increasing the power of the laser beam. Additionally, the Si chip and the mirror portion can be separately fabricated with a simple fabrication process, thereby reducing the cost.

Moreover, the side of one of the Si chip and the first Si chip is connected to the semiconductor laser chip via an electrode. With this configuration, the semiconductor laser chip is fixed on a predetermined position on the side of the Si chip with higher accuracy. Further, by forming the electrode with a metal having an excellent heat dissipation characteristic, heat generated on the semiconductor laser chip can be more efficiently dissipated through the metallic electrode.

Moreover, a surface electrode is provided on a connection surface of the semiconductor laser chip, the connection surface being connected to one of the Si chip and the first Si chip, and wiring is provided on the side of one of the Si chip and the first Si chip and the formation surface of the light-receiving element for detecting a signal, the wiring being connected to the surface electrode.

This configuration facilitates connection, through connection via wiring and the like on an adjacent surface, between wiring on the major surface of one of the Si chip and the first Si chip and the surface electrode surface of the semiconductor laser chip, the surface electrode surface being disposed on the side of one of the Si chip and the first Si chip, thereby achieving more stable electrical connection.

Further, adjacent surfaces are formed between the side and the connection surface such that the length of one of the Si chip and the first Si chip in a direction parallel with the connection surface with the semiconductor laser chip is shorter than the length of the semiconductor laser chip in a direction parallel with the connection surface. With this configuration, it is possible to electrically connect the semiconductor laser chip with higher stability without causing a short circuit on the side of the chip due to solder and the like.

Moreover, the mirror portion includes a light-receiving element for detecting a part of the laser beam passing through the reflection plane. With this configuration, it is possible to easily detect the optical output of a part of the laser beam, thereby estimating the optical output of the overall laser beam. Thus a current value for driving the laser beam is controlled to keep constant the optical output, so that the optical output can be more stably controlled.

Further, the reflection plane of the mirror portion includes a low index surface of Si. With this configuration, a less defective low index surface of Si can be used as the reflection plane of the laser beam, and thus the reflection plane of the mirror portion can be more optically flat.

Moreover, the package includes a package bottom including the base and a package top for extracting the laser beam to the outside of the package. Thus the laser beam can be more efficiently extracted from the package top. At the same time, airtightness can be further increased to prevent external moisture, dust, and so on from entering the package.

Further, the package top includes a diffractive optical element for splitting a part of the laser beam. With this configuration, it is possible to optically couple the light-receiving element for detecting a signal and the semiconductor laser chip to the optical disc and the optical system of the optical pickup outside the package, thereby more efficiently reading information recorded on an optical disc.

### BRIEF DESCRIPTION OF THE DRAWINGS

FIG. 1A is a perspective view showing a packaging state of an integrated optical element acting as a main component of a semiconductor device according to First Embodiment;

FIG. 1B is a schematic block diagram showing the internal configuration of the semiconductor device according to First Embodiment;

FIG. 2A is a sectional view showing a hollow package bottom of the semiconductor device according to First Embodiment;

FIG. 2B is a process sectional view showing a step of applying a fixing member in a method of fabricating the semiconductor device according to First Embodiment;

FIG. 2C is a process sectional view showing a step of fixing the integrated optical element in the method of fabricating the semiconductor device according to First Embodiment;

FIG. 2D is a process sectional view showing a connecting step in the method of fabricating the semiconductor device according to First Embodiment;

FIG. 2E is a process sectional view showing a step of bonding the package top in the method of fabricating the semiconductor device according to First Embodiment;

FIG. 3A is a schematic block diagram showing a semiconductor laser chip and a mirror portion in the semiconductor device according to First Embodiment;

FIG. 3B is a schematic sectional view showing the semiconductor laser chip and the mirror portion in the semiconductor device according to First Embodiment;

FIG. 4A is a schematic block diagram showing the semiconductor laser chip in the semiconductor device according to First Embodiment;

FIG. 4B is a schematic sectional view showing the semiconductor laser chip in the semiconductor device according to First Embodiment;

FIG. 5A is a perspective view showing a packaging state of an integrated optical element acting as a main component of a semiconductor device according to Second Embodiment;

FIG. 5B is a schematic block diagram showing the internal configuration of the semiconductor device according to Second Embodiment;

FIG. 6A is a perspective view showing a packaging state of an integrated optical element acting as a main component of a semiconductor device according to Third Embodiment;

FIG. 6B is a schematic block diagram showing the internal configuration of the semiconductor device according to Third Embodiment;

FIG. 7A is a schematic block diagram showing an optical pickup including a diffractive optical element disposed on a semiconductor device;

FIG. 7B is a schematic block diagram showing an optical pickup including a diffractive optical component disposed outside the semiconductor device;

FIG. 8 is a schematic block diagram showing an optical disc drive of the present invention;

FIG. 9A is a schematic drawing showing an integrated optical element acting as a main part of a conventional semiconductor device;

FIG. 9B is a schematic block diagram showing the internal configuration of the conventional semiconductor device; and

FIG. 10 is a schematic diagram showing the conventional optical pickup including the conventional semiconductor device.

### DESCRIPTION OF THE EMBODIMENTS

Exemplary embodiments of a semiconductor device of the present invention will now be described with reference to the accompanying drawings. As to constituent elements indicated by the same reference numerals in the drawings, the explanation thereof may be omitted.

### First Embodiment

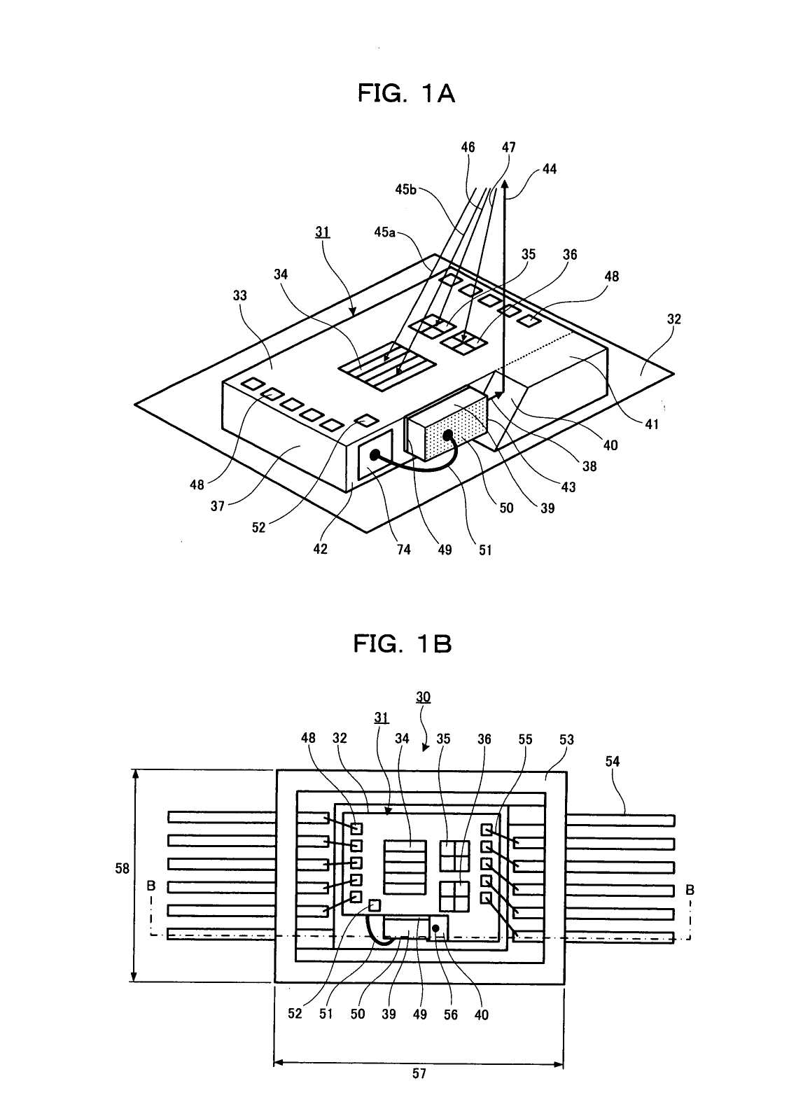

Referring to FIGS. 1 to 4, the configuration of a semiconductor device will be described below according to First Embodiment.

FIG. 1 is a schematic block diagram showing the semiconductor device according to First Embodiment of the present invention. FIG. 1A is a perspective view showing a packaging state of an integrated optical element acting as a main component of the semiconductor device according to First Embodiment. FIG. 1B is a schematic block diagram showing the internal configuration of the semiconductor device according to First Embodiment.

In FIG. 1A, an integrated optical element 31 is mounted on a metal base 32 of a package (not shown). The integrated optical element 31 includes, as main constituent elements, a Si chip 37 having signal processing light-receiving elements 34, 35, and 36 formed on a major surface 33, a semiconductor laser chip 39 for emitting a laser beam 38, and a mirror portion 41 having a reflection plane 40 for reflecting the laser beam 38. The semiconductor laser chip 39 is disposed on a side 42 adjacent to the major surface 33 of the Si chip 37. The laser beam 38 emitted from an end face 43 of the semiconductor laser chip 39 is emitted to the major surface 33 as a laser beam 44 perpendicularly to the major surface 33 through the reflection plane 40 of the mirror portion 41 opposed to the end face 43.

The laser beam 44 is emitted to the outside from a semiconductor device 30 shown in FIG. 1B and reads a signal of an optical disc. After that, the laser beam 44 passes through the path (not shown) of the optical system of the same optical pickup and returns to the semiconductor device 30. The returned laser beam (not shown) is split by a diffractive optical element (not shown) including a plurality of regions formed on the package top (not shown) of the semiconductor device 30. Split laser beams 45a, 45b, 46, and 47 are incident on the signal processing light-receiving elements 34, 35, and 36, and optical signals are read.

The optical signals read by the light-receiving elements 34, 35, and 36 are converted to electric signals. These electric signals are calculated by a signal processing circuit and so on. After that, the electric signals are coupled, via wiring formed on the major surface 33, to electrodes 48 formed on the ends of the major surface 33 of the Si chip 37 and then extracted. Further, the plurality of electrodes 48 are connected to a plurality of lead terminals 54, and the signals of the optical pickup are outputted from the lead terminals 54 to an external circuit. A surface electrode 49 of the semiconductor laser chip 39 is formed on a contact surface with the Si chip 37 and connected to one of the electrodes 48 via wiring (not shown) formed on the major surface 33. The wiring is connected to an electrode formed on the side 42. On the other hand, a rear electrode 50 of the semiconductor laser chip 39 is connected, via a metal wire 51, to a connection electrode 74 formed on the side 42 of the Si chip 37. The connection electrode 74 is connected to an electrode 52 of the major surface 33 via wiring (not shown). The electrode 52 is connected to one of the electrodes 48 via another wiring (not shown) formed on the major surface 33. With such wiring and connection of electrodes, the semiconductor laser chip 39 is current driven by an external current source through the electrodes 48 formed on the ends of the major surface 33 of the Si chip 37.

In the integrated optical element 31 of FIG. 1B, the plurality of electrodes 48 are connected, on the major surface 33 of the Si chip, to the plurality of lead terminals 54 of a package bottom 53 via a plurality of conductive wires 55. The lead terminals 54 are connected to an external circuit, so that the semiconductor laser chip 39 in the semiconductor device 30 and the signal processing light-receiving elements 34, 35, and 36 are driven and operated by an external current source and voltage source. In this way, the laser beam from the semiconductor device 30 is emitted from an apparent light-emitting point 56 of the reflection plane 40, and the laser beam from the optical disc is received by the light-receiving elements 34, 35, and 36.

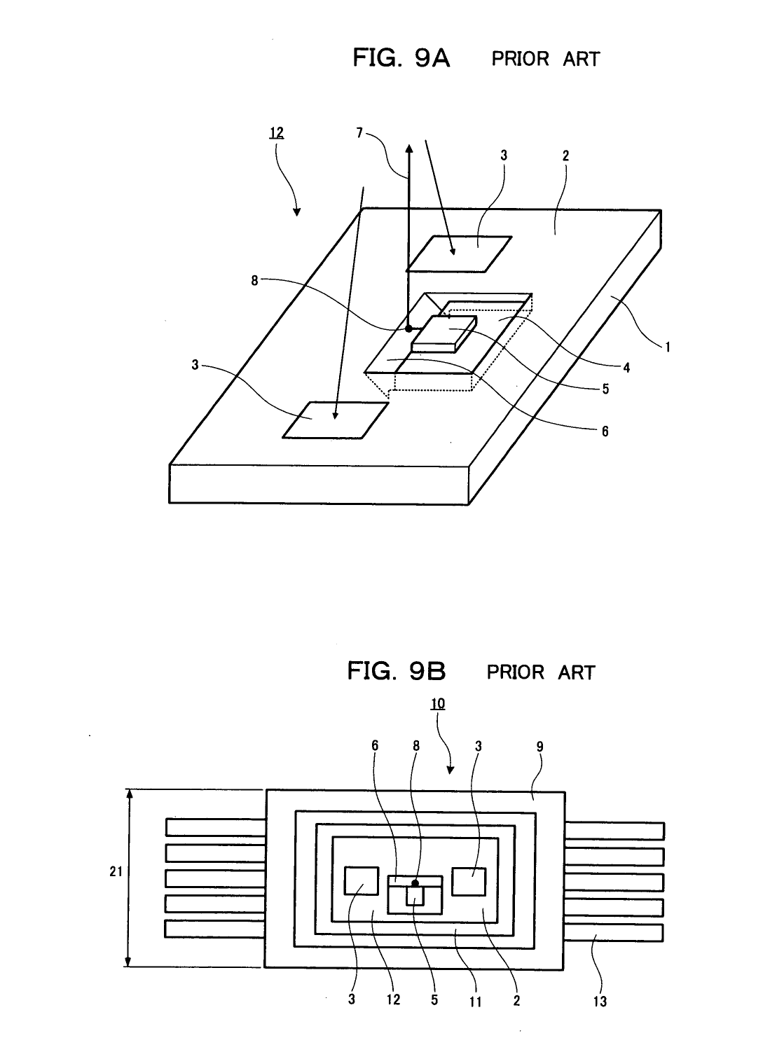

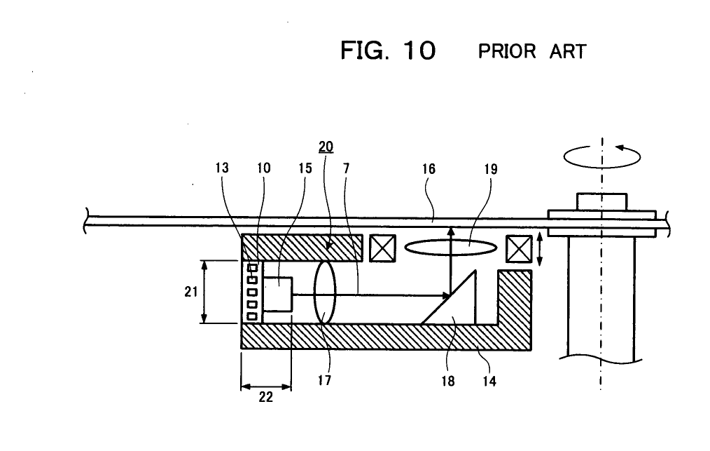

In the semiconductor device 30 of the present embodiment, the semiconductor laser chip 39 is disposed such that the direction of a long side length 57 of the package bottom 53 and a chip length direction become parallel to each other. In other words, the laser beam 38 emitted from the semiconductor laser chip 39 of FIG. 1A also becomes parallel to the long side length 57 of the package bottom 53 of FIG. 1B. Thus in a high power semiconductor laser used for an optical pickup for an optical disc drive, for example, in an AlGaAs semiconductor laser in the 780 nm wavelength band and an AlGaInP semiconductor laser in the 650 nm wavelength band, even when an optical output exceeds 100 mW during pulse output and the cavity length of the semiconductor laser exceeds 1 mm, the short side length of the semiconductor device 30 is not affected. In contrast, in the case where such a semiconductor laser is mounted on the semiconductor device 10 having the conventional configuration of FIG. 9, the short side length 21 is increased relative to the cavity length of the semiconductor laser and thus the optical pickup 20 of FIG. 10 is increased in thickness, interfering with the slimming down and miniaturization of the optical pickup 20. In the present embodiment, the semiconductor laser chip 39 is disposed in parallel with the long side length 57 of the package bottom 53, so that even when the cavity length increases, the short side length of the semiconductor device 30 is not affected. Thus even when using a high-power semiconductor laser, it is possible to reduce the thickness and size of the semiconductor device, thereby slimming down and miniaturizing the optical pickup using the semiconductor laser and the optical disc drive including the optical pickup.

Moreover, as shown in FIGS. 1A and 1B, it is not necessary to dispose the semiconductor laser chip 39 on the major surface 33 of Si and thus a short side length 58 of the package bottom can be further reduced by devising the layout of the light-receiving elements and the signal processing circuit. In other words, since the semiconductor laser chip 39 is disposed on the side 42 of the Si chip 37, it is possible to fabricate the signal processing circuit, wiring, and the like as well as the light-receiving elements on the major surface 33 of the Si chip 37 while effectively using the overall area of the major surface. In the case where the power of the semiconductor laser chip 39 is increased to achieve faster recording on a rewritable optical disc, the cavity length of the semiconductor laser chip 39 is increased. However, in the present embodiment, the cavity length of the semiconductor laser chip 39 is increased in the same direction as the long side length 57 of the semiconductor device 30 and the shape of the semiconductor device 30 does not change, thereby not interfering with the slimming down and miniaturization.

Further, in the semiconductor device 30 of the present embodiment, the semiconductor laser chip 39 is disposed perpendicularly to the major surface 33. This configuration relates to a laser beam outputted from the semiconductor device and the layout of the optical pickup and the optical disc. The intensity distribution of the laser beam outputted from the end face of the semiconductor laser chip is shaped like an ellipse and the optical system of the optical pickup is designed such that the long side of the intensity distribution of the laser beam is placed along the direction of pits serving as data on the optical disc. When the semiconductor laser chip 39 is disposed on the major surface 33 of the integrated optical element 31 such that the direction of the long side length 57 of the package bottom 53 and the length direction of the chip become parallel, the intensity distribution of the laser beam outputted from the semiconductor device rotates by 90°. Therefore, in the present embodiment, the semiconductor laser chip 39 is disposed perpendicularly to the major surface 33 of the integrated optical element 31 and thus the intensity distribution of the laser beam has the same output as a conventional semiconductor device, thereby achieving a thin and small optical pickup.

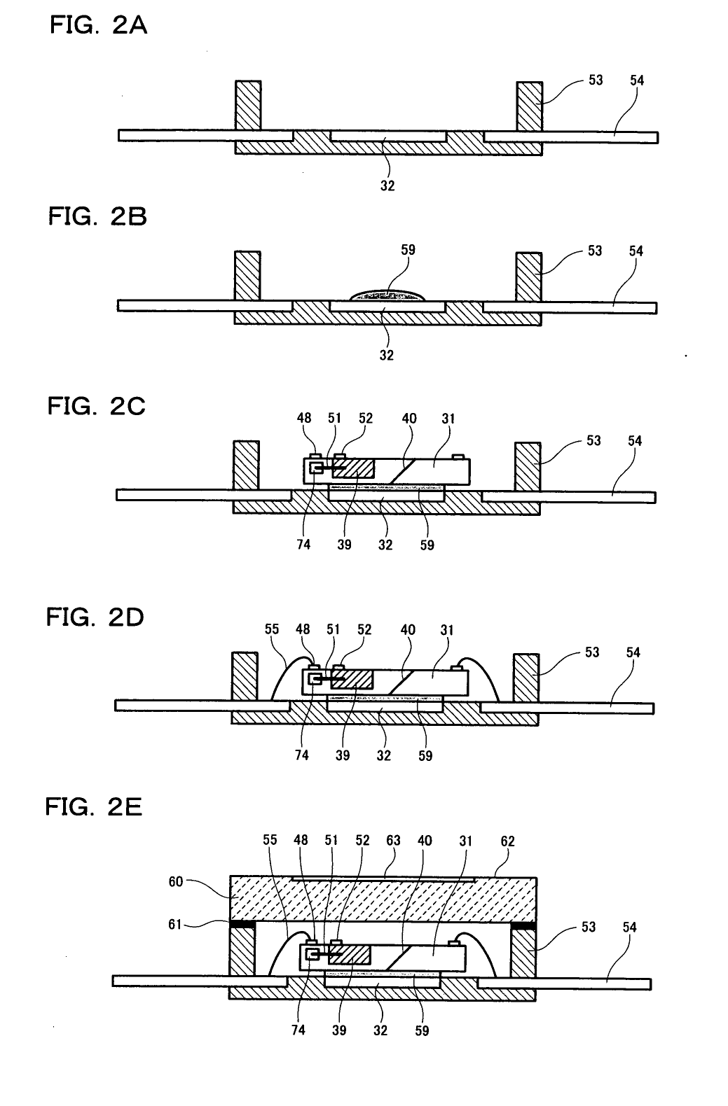

A method of fabricating the semiconductor device 30 of the present embodiment will now be described with reference to process sectional views shown in FIG. 2.

FIG. 2A is a sectional view showing the hollow package bottom of the semiconductor device according to First Embodiment. FIG. 2B is a process sectional view showing a step of applying a fixing member in the method of fabricating the semiconductor device according to First Embodiment. FIG. 2C is a process sectional view showing a step of fixing the integrated optical element in the method of fabricating the semiconductor device according to First Embodiment. FIG. 2D is a process sectional view showing a connecting step in the method of fabricating the semiconductor device according to First Embodiment. FIG. 2E is a process sectional view showing a step of bonding the package top in the method of fabricating the semiconductor device according to First Embodiment. In FIG. 2, all the process sectional views are cut along line B-B of FIG. 1B.

FIG. 2A shows the hollow package bottom 53. The package bottom 53 includes metallic portions and resin portions. The metal base 32 formed in the package and having the semiconductor chip bonded thereon and the lead terminals 54 having conductive wires bonded thereon are not covered with resin, so that the metallic surfaces of the metal base 32 and the lead terminals 54 are exposed. The metal base 32 and the lead terminals 54 are made of a metal and the other package bottom 53 is made of a resin.

First, as shown in FIG. 2B, a proper amount of a fixing member 59 composed of silver paste containing epoxy and polyimide as a base resin is applied on the metal base 32 with a dispenser. The fixing member 59 may be a semi-cured epoxy sheet kneaded with conductive powder. Next, as shown in FIG. 2C, the integrated optical element 31 is disposed on the fixing member 59 so as to be placed on a proper position with respect to the center of the package bottom 53, and then the integrated optical element 31 is heated to be fixed on the metal base 32 with the fixing member 59. In the integrated optical element 31, as shown in FIG. 1A, the signal processing light-receiving elements 34, 35, and 36 are formed on the major surface 33 of the Si chip 37 and the high-power semiconductor laser chip 39 is disposed on the side 42 of the Si chip 37. Further, the Si chip 37 is integrated with the mirror portion 41 and the reflection plane 40 is formed to reflect a high-power laser beam.

Incidentally, the Si chip 37 configured thus is formed on the Si substrate according to a normal bipolar Si process. For example, an i layer of Si is stacked on a p-type Si substrate by an epitaxial process, and then an n-type region and a p-type region are formed by ion implantation to form the light-receiving elements, the transistor, circuit components and so on. Further, the mirror portion 41 is formed as follows: after the light-receiving elements, the transistor, the circuit components and so on are formed, an area other than the formation area of the mirror portion 41 on the major surface 33 is covered with photoresist and the like, and the low index surface of a Si crystal is formed as a mirror surface by, for example, wet etching using an anisotropic etchant.

At this point, when the major surface 33 is, for example, a plane (100) having an off angle of about 10° with respect to a direction <110>, the reflection plane 40 is formed at 45° with respect to the major surface 33. Further, the reflection plane 40 is formed into an exposed plane (111) serving as one of low index surfaces of Si by the anisotropic etchant. Thus a preferable reflection plane can be formed with optical flatness. The reflectivity of the reflection plane 40 can be increased to 95% or more by applying a metallic thin film on the plane (111). To be specific, for example, a SiN film having a thickness of 300 nm is formed on the reflection plane 40 by plasma CVD, and then a Ti film having a thickness of 100 nm and an Au film having a thickness of 500 nm are sequentially stacked as metallic thin films by metallic vapor deposition.

Next, on the side having the semiconductor laser chip 39 on the Si chip 37 fabricated thus, an electrode (not shown) connected to a surface electrode (not shown) of the semiconductor laser chip 39 is formed, wiring for connecting the electrode and the electrode 48 on the major surface 33 is formed, the connection electrode 74 connected from the rear electrode of the semiconductor laser chip 39 via the conductive wire 51 is formed, and wiring for connecting the connection electrode and the electrode 52 on the major surface 33 is formed. In this process, for example, a part other than the electrodes and wiring on the side is masked with photoresist and the like, Ti/Au is evaporated by vapor deposition and the like, and the electrodes and wiring are formed by lift-off.

Further, on the major surface 33 of Si of the integrated optical element 31, the electrode 52 connected to the connection electrode 74 via wiring is formed and the electrodes 48 connected to the lead terminals 54 via conductive wires are formed. The connection electrode 74 is connected to the semiconductor laser chip 39 via the conductive wire 51 on the side of the Si chip 37. With the plurality of electrodes 48, output subjected to signal processing by the light-receiving elements, the transistor, the circuit components and the like on the Si major surface is outputted as signal outputs of the optical pickup from the lead terminals 54 to an external circuit of the package.

As shown in FIG. 2D, the integrated optical element 31 formed thus is connected to the lead terminals 54 of the package bottom 53 via conductive wires. In other words, the electrodes 48 on the Si major surface 33 are connected to the lead terminals 54 via, for example, the conductive wires 55 made of Al.

Finally, as shown in FIG. 2E, a package top 60 is bonded as a cap component to the package bottom 53 with an adhesive 61. The package top 60 is formed of, for example, a transparent resin material such as polyolefin by injection molding. The transparent resin material allows the passage of a number of laser beams. A diffractive optical element 63 for splitting a part of a laser beam is formed on an outer surface 62 of the package top 60. A laser beam reflected and returned from the optical disc (not shown) is partially diffracted by the diffractive optical element 63 and guided to the signal processing light-receiving elements 34, 35, and 36 on the major surface 33, so that optical signals are received.

When a diffractive optical component is disposed outside the semiconductor device in the optical pickup, the diffractive optical element 63 is not formed on the package top 60.

With this configuration, the semiconductor laser chip is reliably fixed on the side of the Si chip and connected to the wiring on the major surface. Thus it is possible to fabricate a semiconductor device reduced in thickness and size with electrical and optical stability.

Further, for a rewritable optical disc, it is important to control the optical output of a high-power semiconductor laser. When the optical output increases more than necessary, information recorded on the optical disc may be erased or a heavy load may be applied to the semiconductor laser. Further, when the optical output is smaller than a predetermined output, previously recorded contents may be insufficiently erased during recording on the optical disc, so that recording may be incompletely performed. Therefore, it is necessary to control the optical output of the high-power semiconductor laser with uniform precision. For this purpose, it is necessary to partially detect a laser beam emitted from the high-power semiconductor laser to the optical disc and control the current value of a laser power supply in such a manner as to keep constant the optical output based on the detected value.

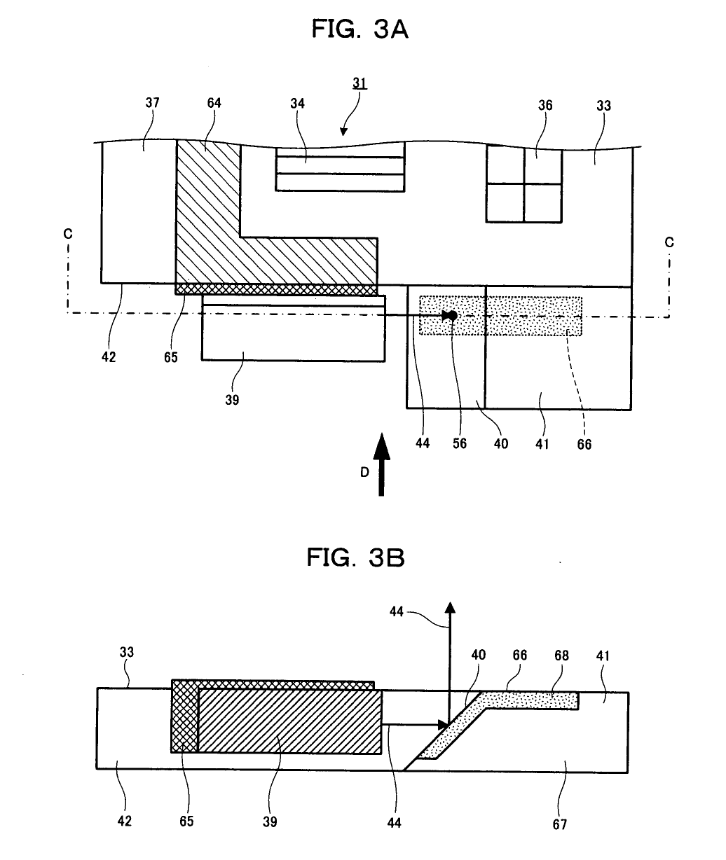

Referring to FIG. 3, the following will discuss the light-receiving elements formed on the mirror portion 41 to detect a part of the optical output of the high-power semiconductor laser.

FIG. 3A is a schematic block diagram showing the semiconductor laser chip and the mirror portion in the semiconductor device according to First Embodiment. In FIG. 3A, the semiconductor laser chip 39 of the integrated optical element 31 and the mirror portion 41 are enlarged and viewed from the top.

As shown in FIG. 3A, the light-receiving elements 34 and 36 and wiring 64 for applying current to the semiconductor laser chip 39 are formed on the major surface 33 of the Si chip 37. Further, wiring 65 continuously connected from the wiring 64 to the surface electrode of the semiconductor laser chip 39 is formed on the side 42 of the Si chip 37. The semiconductor laser chip 39 and the wiring 65 are connected with solder (not shown).

Incidentally, the laser beam 44 emitted from the semiconductor laser chip 39 is reflected on the apparent light-emitting point 56 of the reflection plane 40 of the mirror portion 41, and then the laser beam 44 is emitted upward in a perpendicular direction and reaches the optical disc (not shown). A metallic thin film or a dielectric thin film is formed on the Si reflection plane and, for example, about 1% to 2% of the laser beam 44 is allowed to pass through the reflection plane 40 when the laser beam 44 is reflected on the reflection plane 40, so that a part of the laser beam 44 is received by a light-receiving element 66 for an optical output monitor.

FIG. 3B is a schematic sectional view showing the semiconductor laser chip and the mirror portion in the semiconductor device according to First Embodiment. FIG. 3B is also a schematic block diagram showing an enlarged sectional view showing a part around the semiconductor laser chip 39 and the light-receiving element 66 for an optical output monitor, taken along line C-C of FIG. 3A and viewed from the direction of an arrow D.

As shown in FIG. 3B, the light-receiving element 66 for an optical output monitor is fabricated by, for example, forming an n-type region 68 to have a PN junction. The region 68 is formed by ion implanting As acting as n-type dopant on a p-type Si substrate 67. This configuration makes it possible to estimate the optical output of the overall laser beam and control the current value for driving the laser beam so as to accurately keep a desired optical output. Therefore, it is possible to more stably output the laser beam with a constant output from the semiconductor device.

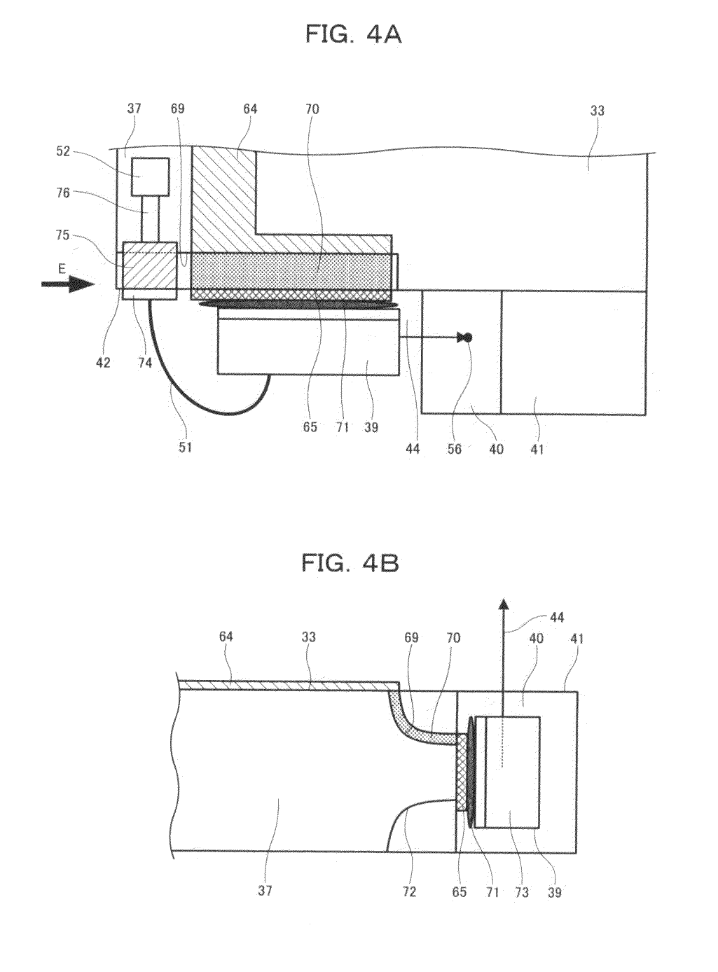

Referring to FIG. 4, the packaging structure of the semiconductor laser chip will be described below with reference to a schematic block diagram showing an enlarged part around the semiconductor laser chip.

FIG. 4A is a schematic block diagram showing the semiconductor laser chip in the semiconductor device according to First Embodiment. In FIG. 4A, a main part having the semiconductor laser chip 39 mounted on the side 42 of the Si chip 37 is viewed from the top. FIG. 4B is a schematic sectional view showing the semiconductor laser chip in the semiconductor device according to First Embodiment. In FIG. 4B, a main packaging part of the semiconductor laser chip 39 is viewed from the direction of an arrow E of FIG. 4A.

As shown in FIGS. 4A and 4B, a taper and a groove are formed such that on the contact surface with the semiconductor laser chip 39 of the Si chip 37, the length of the Si chip 37 in a perpendicular direction to the major surface 33 is shorter than the length of the semiconductor laser chip 39 in the perpendicular direction to the major surface 33, and an adjacent surface 69 and an adjacent surface 72 are formed next to the side 42 for mounting the semiconductor laser chip 39. As wiring for applying current to the semiconductor laser chip 39, the wiring 64 on the major surface 33 and wiring 70 on the adjacent surface 69 are continuously formed and connected to the wiring 65 of the side 42. The surface electrode (not shown) of the semiconductor laser chip 39 and the wiring 65 are connected via solder 71. Further, the rear electrode (not shown) of the semiconductor laser chip 39 is connected to the connection electrode 74 on the side of the Si chip 37 via the conductive wire 51. The connection electrode 74 is connected to wiring 75 on the adjacent surface 69 via wiring (not shown) on the side, and then is connected to the electrode 52 via wiring 76 on the major surface 33.

By forming the adjacent surface 69 and the adjacent surface 72 thus, the semiconductor laser chip 39 can be more accurately fixed on a predetermined position on the side 42 of the Si chip 37. Further, by forming the wiring 65 with a metal having an excellent heat dissipation characteristic, for example, gold, heat generated on the semiconductor laser chip can be more efficiently dissipated through the metallic wiring 65. In this configuration, heat is efficiently dissipated through the continuing electrodes 70 and 64.

Moreover, as is evident from FIG. 4B, even when a large amount of solder is used for soldering, the solder flows to the adjacent surfaces 69 and 72 without swelling on the side 42 of the semiconductor laser chip 39, achieving high reliability without causing a short circuit and so on.

### Second Embodiment

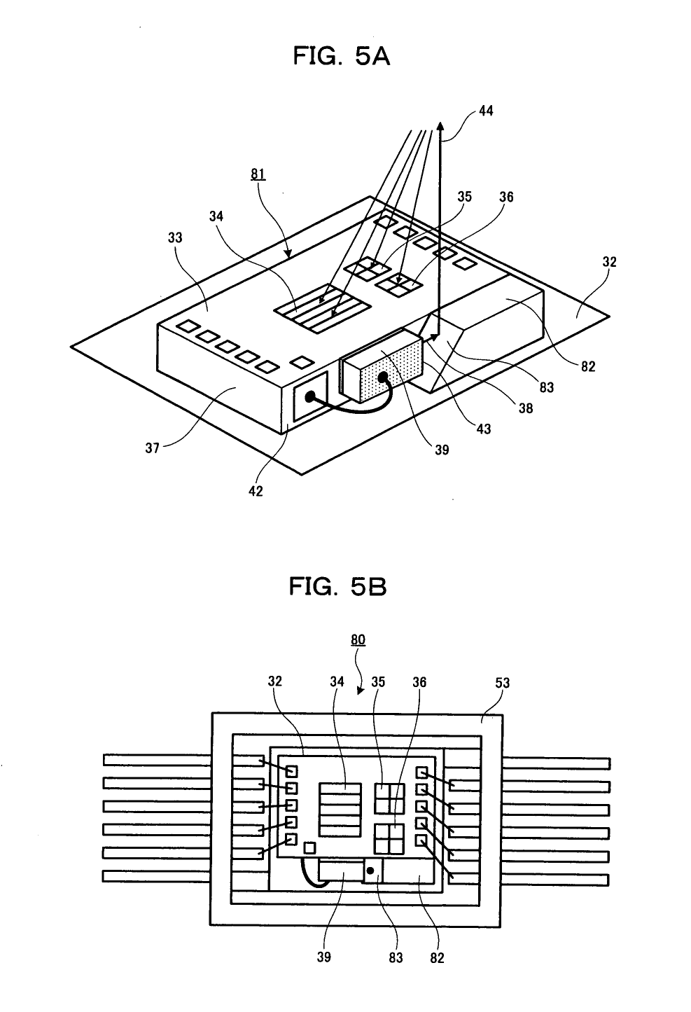

Referring to FIG. 5, the configuration of a semiconductor device will be described below according to Second Embodiment of the present invention.

FIG. 5A is a perspective view showing a packaging state of an integrated optical element acting as a main component of the semiconductor device according to Second Embodiment. FIG. 5A shows a packaging state of an integrated optical element 81 and a mirror portion 82 acting as main components of a semiconductor device 80 according to the present embodiment. FIG. 5B is a schematic block diagram showing the internal configuration of the semiconductor device according to Second Embodiment. In FIG. 5B, the package top of the semiconductor device 80 is removed to show the internal configuration of the semiconductor device 80.

In FIG. 5A, an integrated optical element 81 is mounted on a metal base 32 of a package (not shown). Unlike First Embodiment, the integrated optical element 81 and the mirror portion 82 are not integrated but mounted as separated components.

The integrated optical element 81 includes, as main constituent elements, a Si chip 37 having signal processing light-receiving elements 34, 35, and 36 formed on a major surface 33, a semiconductor laser chip 39 for emitting a laser beam 38, and the mirror portion 82 having a reflection plane 83 for reflecting the laser beam 38. The semiconductor laser chip 39 is disposed on a side 42 adjacent to the major surface 33 of the Si chip 37. The laser beam 38 emitted from an end face 43 of the semiconductor laser chip 39 is emitted to the major surface 33 as a laser beam 44 perpendicularly to the major surface 33 through the reflection plane 83 of the mirror portion 82 mounted to be opposed to the end face 43.

A method of reading signals of an optical disc is the same as that of First Embodiment and thus the explanation thereof is omitted. By fabricating the integrated optical element 81 and the mirror portion 82 as separated components, only a suitable step for each of the components is necessary and thus the fabrication process can be simplified, thereby achieving low cost. To be specific, the mirror portion 82 can be obtained by, for example, forming a strip of a mirror bar and cutting the mirror bar into pieces. Since a process for preparing a mirror is not necessary, the integrated optical element 81 may be formed on the conductive Si substrate through a normal bipolar Si process.

In the above explanation, the mirror portion 82 is made of a Si semiconductor material. Since the mirror portion 82 can be separately formed, a glass material and a metallic material may be used. In other words, any material may be used as long as the laser beam 38 can be reflected without changing the intensity, phase, and distribution state of the laser beam 38.

FIG. 5B is a schematic block diagram of the semiconductor device 80. In FIG. 5B, the integrated optical element 81 and mirror portion 82 illustrated in FIG. 5A are bonded to a package bottom 53. The integrated optical element 81 and the mirror portion 82 are not integrated into a single part. In First Embodiment, since the mirror portion 41 is integrated with the Si chip 37, the primary mounting accuracy of the semiconductor device 30 is determined only by mounting the semiconductor laser chip 39 on a predetermined mounting position. In the present embodiment, the primary mounting accuracy is determined by the mounting accuracy of the semiconductor laser chip 39 and the optical mounting accuracy of the mirror portion 82 relative to the semiconductor laser chip 39.

However, by bonding the flat side 42 of the Si chip 37 and the flat side of the mirror portion 82 and integrating the Si chip 37 and the mirror portion 82 into a single part beforehand, only the precise mounting accuracy of the semiconductor laser chip 39 is necessary.

When the mirror portion is formed of a semiconductor material such as a Si semiconductor, a light-receiving element for an optical output monitor for detecting a part of a laser beam may be formed on the mirror portion as described in First Embodiment shown in FIG. 3.

Further, as described in First Embodiment shown in FIG. 4, adjacent surfaces may be formed between a major surface 33 and the side 42 of the Si chip 37 to form wiring for connecting the electrodes of the semiconductor laser chip 39, a connection electrode, and electrodes on the major surface.

As described above, even in the case where the integrated optical element and the mirror portion are separately formed, the semiconductor laser chip is disposed in parallel with the long side length of the package bottom as in First Embodiment, so that even when the cavity length increases, the short side length of the semiconductor device is not affected. Thus even when increasing the power of a semiconductor laser, it is possible to reduce the thickness and size of the semiconductor device, thereby slimming down and miniaturizing an optical pickup using the semiconductor device and an optical disc drive including the optical pickup.

### Third Embodiment

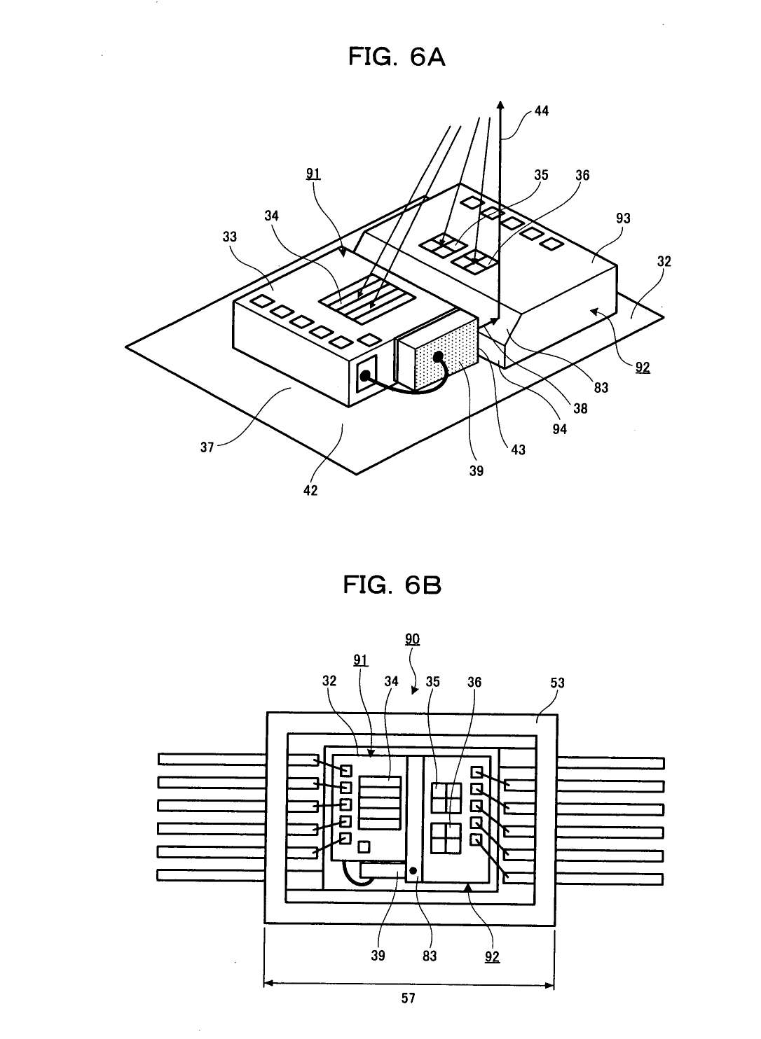

Referring to FIG. 6, the configuration of a semiconductor device will be described below according to Third Embodiment of the present invention.

FIG. 6A is a perspective view showing a packaging state of an integrated optical element acting as a main component of the semiconductor device according to Third Embodiment. FIG. 6A shows a packaging state of a first Si chip 91 and a second Si chip 92. A semiconductor laser chip 39 serving as a main component of a semiconductor device 90 of the present embodiment is mounted on the first Si chip 91. FIG. 6B is a schematic block diagram showing the internal configuration of the semiconductor device according to Third Embodiment. In FIG. 6B, the package top of the semiconductor device 90 is removed to show the internal configuration of the semiconductor device 90. In this configuration, the first Si chip 91 is an integrated optical element having the semiconductor laser chip 39 mounted thereon. The second Si chip 92 is also an integrated optical element. On the second Si chip 92, light-receiving elements, an electronic circuit, and a mirror including a reflection plane are integrated.

In FIG. 6A, the first Si chip 91 and the second Si chip 92 serving as integrated optical elements are mounted on a metal base 32 of a package (not shown). The constituent elements of First and Second Embodiments are separately mounted into the two Si chips to perform the functions.

The first Si chip 91 includes a signal processing light-receiving element 34 formed on a major surface 33 and a semiconductor laser chip 39 mounted on a side 42. The second Si chip 92 includes signal processing light-receiving elements 35 and 36 formed on a major surface 93 and a mirror reflection plane 83 formed on a side of the second Si chip 92. The first Si chip and the second Si chip are mounted on a metal base 32 with a precisely determined positional relationship of assembly. A laser beam 38 emitted from an end face 43 of the semiconductor laser chip 39 is emitted as a laser beam 44 to the major surface 93 in a perpendicular direction to the major surface 93 through the mirror reflection plane 83 of the second Si chip 92 mounted to be opposed to the end face 43.

A method of reading signals of an optical disc is the same as that of First Embodiment and thus the explanation thereof is omitted. By fabricating the first Si chip 91 and the second Si chip 92 as separated components, the fabrication of the Si element having a complicated shape in First Embodiment is not necessary. Further, in a process of forming the mirror reflection plane 83 on the side of the second Si chip 92, the mirror reflection plane 83 is formed over the side, so that the process can be more simplified as compared with the process of First Embodiment. In other words, as in First Embodiment, the semiconductor laser chip is disposed in parallel with the long side length of a package bottom, so that even when the cavity length increases, the short side length of the semiconductor device is not affected. Thus even when increasing the power of a semiconductor laser, it is possible to reduce the thickness and size of the semiconductor device, thereby slimming down and miniaturizing an optical pickup using the semiconductor device and an optical disc drive including the optical pickup. Further, the constituent elements are separately mounted on the two chips and the shapes of the Si chips are simplified, increasing the mass productivity. Thus the cost of the overall semiconductor device 90 can be reduced.

FIG. 6B is a schematic block diagram of the semiconductor device 90. In FIG. 6B, the first Si chip 91 and second Si chip 92 illustrated in FIG. 6A are bonded to a package bottom 53. As shown in FIG. 6A, a lower flat surface 94 of the mirror reflection plane 83 of the second Si chip 92 and the opposing surface of the first Si chip 91 are butt-joined to each other, obtaining the assembling accuracy of the first Si chip 91 and the second Si chip 92 in one direction. Therefore, when the assembling accuracy is obtained after the Si chips are bonded using low index surfaces as the flat surfaces of the Si chips, the primary mounting accuracy of the semiconductor device 90 is determined only by mounting the semiconductor laser chip 39 on a predetermined mounting position.

Further, as described in First Embodiment shown in FIG. 4, adjacent surfaces may be formed between the major surface 33 and the side 42 of the first Si chip 91 to form wiring for connecting the electrodes of the semiconductor laser chip 39, a connection electrode, and electrodes on the major surface.

### Fourth Embodiment

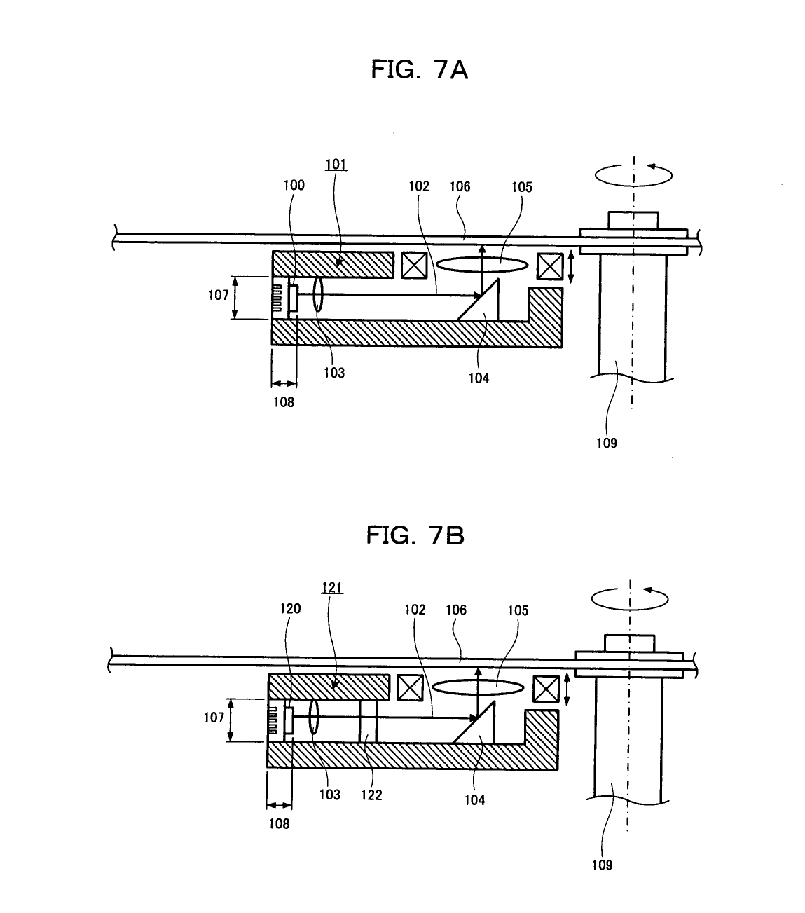

Referring to FIG. 7, an optical pickup including any one of the semiconductor devices of First to Third Embodiments will be described below.

FIG. 7A is a schematic block diagram showing the optical pickup including a diffractive optical element disposed on the semiconductor device.

As shown in FIG. 7A, the optical pickup is configured such that a semiconductor device 100 according to any one of First to Third Embodiments is mounted in a housing making up the optical pickup. A raising mirror 104 is placed on one end opposed to the semiconductor device 100 in the direction of a laser beam emitted from the semiconductor device 100 in the housing, and the raising mirror 104 bends the emitted beam by 90°. An opening is provided on the housing along the traveling direction of the bent laser beam. The laser beam passes through an objective lens 105 provided in the opening and is emitted to an optical disc 106. An optical component 103 is provided between the semiconductor device 100 and the raising mirror 104 in the housing. In an optical pickup 101 configured thus, a laser beam 102 emitted from a semiconductor laser chip (not shown) of the semiconductor device 100 is collimated into a parallel beam by the optical component 103 including, for example, a collimate lens, and the optical path is bent by 90° by the raising mirror 104. After that, the parallel beam is brought into focus, by the objective lens 105, on a pit recorded on the optical disc 106. The laser beam 102 having read a signal on the pit is reflected on the optical disc 106 and travels backward the same path to return to the semiconductor device 100. At this point, the laser beam 102 is split by a diffractive optical element (not shown) formed in a package top of the semiconductor device 100 and is incident on a light-receiving element (not shown), and the signal recorded on the optical disc is read. The optical disc 106 is rotated by a rotating shaft 109 rotated by a spindle motor.

The thickness of the optical pickup 101 configured thus is determined by a width 107 of the semiconductor device 100 and a projected area serving as an index of miniaturization is affected by a height 108 of the semiconductor device 100. In the present embodiment, the thickness of the optical pickup 101 is 80% of that of the conventional optical pickup 20 shown in FIG. 9 and the projected area of the optical pickup 101 is 75% of that of the optical pickup 20.

FIG. 7B is a schematic block diagram showing an optical pickup including a diffractive optical component disposed outside the semiconductor device. FIG. 7B is also a schematic diagram showing an optical pickup 121 including a semiconductor device 120 not having a diffractive optical element formed on a package top, out of the semiconductor devices according to First to Third Embodiments.

A laser beam 102 emitted from a semiconductor laser chip (not shown) of the semiconductor device 120 in FIG. 7B is collimated into a parallel beam by an optical component 103 including, for example, a collimate lens, and the optical path is bent by 90° by a raising mirror 104. After that, the parallel beam is brought into focus, by an objective lens 105, on a pit recorded on an optical disc 106. The laser beam 102 having read a signal on the pit is reflected on the optical disc 106 and travels backward the same path to return to the semiconductor device 120. At this point, the laser beam 102 is split by a diffractive optical component 122 disposed between the optical component 103 and the raising mirror 104, and the laser beam 102 is condensed through the optical component 103 and incident on a light-receiving element (not shown), and a signal recorded on the optical disc is read. The optical disc 106 is rotated by a rotating shaft 109 rotated by a spindle motor.

The thickness of the optical pickup 121 configured thus is determined by a width 107 of the semiconductor device 120 and a projected area serving as an index of miniaturization is affected by a height 108 of the semiconductor device 120. In the present embodiment, the thickness of the optical pickup 101 is 80% of that of the conventional optical pickup 20 shown in FIG. 9 and the projected area of the optical pickup 101 is 75% of that of the optical pickup 20.

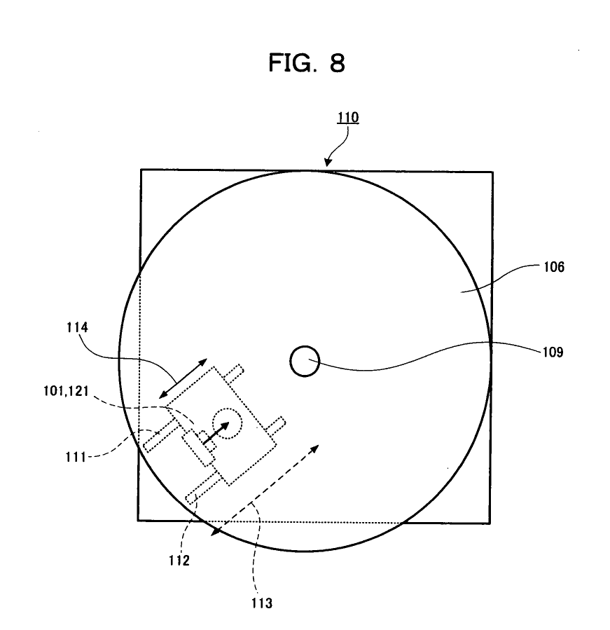

Referring to FIG. 8, an optical disc drive using the optical pickup of FIG. 7 will be described below.

FIG. 8 is a schematic block diagram showing the optical disc drive of the present invention. FIG. 8 shows an optical disc drive 110 using one of the optical pickups 101 and 121 of the present embodiment.

In FIG. 8, the optical disc drive 110 drives the rotating shaft 109 by means of a drive mechanism for rotating the optical disc 106. For recording/reproduction of a signal on the optical disc 106, one of the optical pickups 101 and 121 is moved along a moving direction 113 by support shafts 111 and 112 of a traverse mechanism movable in the radial direction of the disc. Since the semiconductor device 100 reduced in size and thickness according to the present invention is included in one of the optical pickups 101 and 121, one of the optical pickups 101 and 121 is reduced in thickness and size as illustrated in FIG. 8. Therefore, one of the optical pickups 101 and 121 has a small width 114 in the radial direction and thus the optical disc drive 110 can be also reduced in size and thickness.

In the above explanation, the high-power semiconductor laser is one of an AlGaAs semiconductor laser in the 780 nm wavelength band and an AlGaInP semiconductor laser in the 650 nm wavelength band. A blue laser and an ultraviolet light laser may be used as long as the laser is a high-power semiconductor laser usable for a rewritable optical disc. Further, a multi-wavelength laser including a dual-wavelength laser and a three-wavelength laser may be used. The semiconductor chip may be monolithically formed and a number of chips may be mounted in a hybrid manner.

Although the three light-receiving elements are mounted in the above explanation, the number of light-receiving elements can be optionally set according to the configuration of equipment.

Further, although the chip having the light-receiving elements formed on the major surface is made of a Si material in the above explanation, the chip may be made of other materials capable of forming the light-receiving elements, for example, materials including AlGaAs, AlGaInP, AlGaN, SiC, and SiGeC of compound semiconductors.

Moreover, although the package is a resin mold package in the above explanation, other packages including a resin package, a metallic package, and a ceramic package may be used and the material and form of the package are not limited as long as the package is used for an optical device.

What is claimed is:

1. A semiconductor device for emitting and receiving a laser beam, comprising:
a package for packaging the semiconductor device;
a Si chip formed on a base of the package and including one or a plurality of light-receiving elements for detecting a signal;
a semiconductor laser chip disposed on a Si chip side adjacent to a connection surface with the base such that a cavity length direction and a long side direction of the package are aligned with each other, the semiconductor laser chip emitting a laser beam from an end face of the semiconductor laser chip;
a mirror portion having a reflection plane for reflecting the laser beam perpendicularly to a major surface of the package; and
a lead terminal electrically connected to an electrode of the Si chip and serving as an external electrode of the semiconductor device.

2. The semiconductor device according to claim 1, wherein the Si chip and the mirror portion are integrated into a single part.

3. The semiconductor device according to claim 1, wherein the Si chip and the mirror portion are separated from each other.

4. A semiconductor device for emitting and receiving a laser beam, comprising:
a package for packaging the semiconductor device;
a first Si chip formed on a base of the package and including one or a plurality of light-receiving elements for detecting a signal;
a second Si chip formed on the base of the package and including one or a plurality of light-receiving elements for detecting a signal;
a semiconductor laser chip disposed on a first Si chip side adjacent to a connection surface with the base such that a cavity length direction and a long side direction of the package are aligned with each other, the semiconductor laser chip emitting a laser beam from an end face of the semiconductor laser chip;
a mirror portion formed on the second Si chip and having a reflection plane for reflecting the laser beam perpendicularly to a major surface of the package; and
a lead terminal electrically connected to an electrode of one of the first Si chip and the second Si chip and serving as an external electrode of the semiconductor device.

5. The semiconductor device according to claim 1, wherein the side of one of the Si chip and the first Si chip is connected to the semiconductor laser chip via an electrode.

6. The semiconductor device according to claim 4, wherein the side of one of the Si chip and the first Si chip is connected to the semiconductor laser chip via an electrode.

7. The semiconductor device according to claim 1, further comprising:
a surface electrode on a connection surface of the semiconductor laser chip, the connection surface being connected to one of the Si chip and the first Si chip, and
wiring on the side of one of the Si chip and the first Si chip and a formation surface of the light-receiving element for detecting a signal, the wiring being connected to the surface electrode.

8. The semiconductor device according to claim 4, further comprising:
a surface electrode on a connection surface of the semiconductor laser chip, the connection surface being connected to one of the Si chip and the first Si chip, and
wiring on the side of one of the Si chip and the first Si chip and a formation surface of the light-receiving element for detecting a signal, the wiring being connected to the surface electrode.

9. The semiconductor device according to claim 1, further comprising adjacent surfaces formed between the side and the connection surface such that a length of one of the Si chip and the first Si chip in a direction parallel with the connection surface with the semiconductor laser chip is shorter than a length of the semiconductor laser chip in a direction parallel with the connection surface.

10. The semiconductor device according to claim 4, further comprising adjacent surfaces formed between the side and the connection surface such that a length of one of the Si chip and the first Si chip in a direction parallel with the connection surface with the semiconductor laser chip is shorter than a length of the semiconductor laser chip in a direction parallel with the connection surface.

11. The semiconductor device according to claim 1, wherein the mirror portion includes a light-receiving element for detecting a part of the laser beam passing through the reflection plane.

12. The semiconductor device according to claim 4, wherein the mirror portion includes a light-receiving element for detecting a part of the laser beam passing through the reflection plane.

13. The semiconductor device according to claim 1, wherein the reflection plane of the mirror portion includes a low index surface of Si.

14. The semiconductor device according to claim 4, wherein the reflection plane of the mirror portion includes a low index surface of Si.

15. The semiconductor device according to claim 1, wherein the package includes a package bottom including the base and a package top for extracting the laser beam to an outside of the package.

16. The semiconductor device according to claim 4, wherein the package includes a package bottom including the base and a package top for extracting the laser beam to an outside of the package.

17. The semiconductor device according to claim 15, wherein the package top includes a diffractive optical element for splitting a part of the laser beam.

18. The semiconductor device according to claim 16, wherein the package top includes a diffractive optical element for splitting a part of the laser beam.
